(19) United States
(12) Patent Application Publication
(10) Pub. No.: US 2025/0392310 A1
(43) Pub. Date: Dec. 25, 2025

(54) LEVEL SHIFTING DEVICE STRUCTURE

(71) Applicant: Silergy Semiconductor Technology (Hangzhou) LTD, Hangzhou (CN)

(72) Inventors: Bo Zhao, Hangzhou (CN); Jin Jin, Hangzhou (CN); Wenjie Wu, Hangzhou (CN); Lingfang Zhang, Hangzhou (CN)

(21) Appl. No.: 19/219,080

(22) Filed: May 27, 2025

(30) Foreign Application Priority Data
Jun. 25, 2024 (CN) 202410832316.0

(51) Int. Cl. H03K 19/0185

(52) U.S. Cl. CPC H03K 19/018507

(57) ABSTRACT

A level-shifting device structure can include: a level-shifting MOS transistor located in a semiconductor region, where the level-shifting MOS transistor comprises a source region, a drain region, and a doped region; an isolation structure extending from both sides of the doped region to form a closed ring shape, in order to divide the semiconductor region into a high-voltage side region enclosed by the isolation structure and a low-voltage side region located outside the isolation structure; and where the drain region is disposed in the high-voltage side region, and the source region is disposed in the low-voltage side region.

### RELATED APPLICATIONS

This application claims the benefit of Chinese Patent Application No. 202410832316.0, filed on Jun. 25, 2024, which is incorporated herein by reference in its entirety.

### FIELD OF THE INVENTION

The present invention generally relates to the field of power electronics, and more particularly to level-shifting devices and structures.

### BACKGROUND

A switched-mode power supply (SMPS), or a “switching” power supply, can include a power stage circuit and a control circuit. When there is an input voltage, the control circuit can consider internal parameters and external load changes, and may regulate the on/off times of the switch system in the power stage circuit. Switching power supplies have a wide variety of applications in modern electronics. For example, switching power supplies can be used to drive light-emitting diode (LED) loads. Level-shifting devices and structures can be used in power supplies, as well as in a wide variety of other circuitry.

### BRIEF DESCRIPTION OF THE DRAWINGS

FIG. 1 is a schematic block diagram of an example level-shifting device.

FIG. 2A is a top view of a first example level-shifting device structure, in accordance with embodiments of the present invention.

FIG. 2B is a partially enlarged view of a first example level-shifting device structure, in accordance with embodiments of the present invention.

FIG. 3 is a cross-sectional view of the first example level-shifting device structure along a line ‘cd’ in FIG. 2A, in accordance with embodiments of the present invention.

FIG. 4A is a top view of a second example level-shifting device structure, in accordance with embodiments of the present invention.

FIG. 4B is a partially enlarged view of a second example level-shifting device structure, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

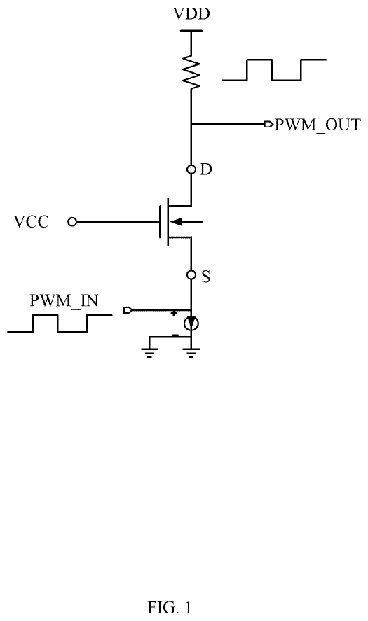

Referring now to FIG. 1, shown is a schematic block diagram of an example level-shifting device. The level-shifting device can include a MOS transistor, and the MOS transistor can be a high-voltage level-shifting transistor. When the gate terminal of the MOS transistor is connected to voltage VCC, the current channel of the MOS transistor may be turned on. The MOS transistor can include source terminal S which may serve as the low-voltage side current input, and drain terminal D which can connect to high-voltage power terminal VDD through a resistor and may serve as the high-voltage side current output. When a pulse signal PWM-IN is input from the low-voltage side current input, a signal PWM-OUT can correspondingly be output across the resistor at the high-voltage side.

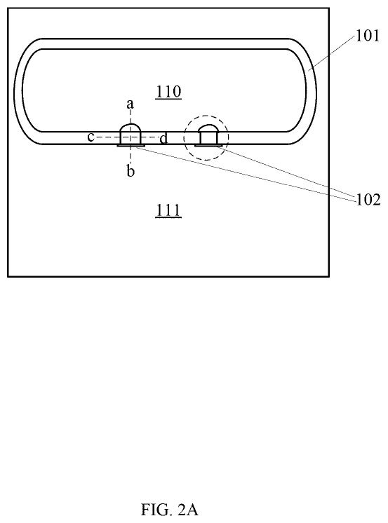

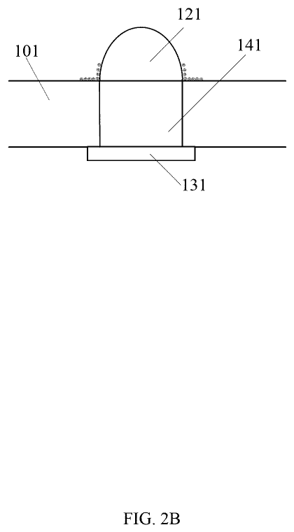

Referring now to FIGS. 2A and 2B, shown are a top view diagram and a partially enlarged view block diagram, respectively, of a first example level-shifting device structure, in accordance with embodiments of the present invention. FIG. 2B is an enlarged view of the level-shifting device structure within the dashed box shown in FIG. 2A. Particular embodiments may provide a level-shifting device structure, which can include level-shifting MOS transistor 102 located in a semiconductor region. Level-shifting MOS transistor 102 can include a source terminal coupled to a low-voltage side circuit, and a drain terminal coupled to a high-voltage side circuit. As shown in FIG. 2B, level-shifting MOS transistor 102 can include source region 131, drain region 121, and doped region 141.

The level-shifting device structure can also include isolation structure 101, which can extend from both sides of doped region 141 to form a closed ring shape, thereby dividing the semiconductor region into high-voltage side region 110 enclosed by the isolation structure and low-voltage side region 111 located outside the isolation structure. Drain region 121 can be disposed in high-voltage side region 110, and source region 131 may be disposed in low-voltage side region 111. The low-voltage side circuit can be located in low-voltage side region 111, and the high-voltage side circuit may be located in high-voltage side region 110. Isolation structure 101 may provide electrical isolation between the high-voltage and low-voltage side circuits. In this example, the entire thickness of isolation structure 101 can be set to be the same; that is, the thickness of all parts of the isolation structure may be the same thickness.

In particular embodiments, the level-shifting MOS transistor can be a laterally-diffused metal-oxide-semiconductor (LDMOS). The shape of drain region 121 can be set as a semi-ellipse, in order to reduce charge accumulation at the junction of drain region 121 and the isolation structure. In this particular example, the level-shifting MOS transistor can be an N-type MOS transistor, and the isolation structure can be P-type doped.

In particular embodiments, the high-voltage side circuit can include a high-voltage control circuit, a high-voltage driver circuit, and high-voltage power devices, among others. Further, the low-voltage side circuit can include a low-voltage control circuit, a low-voltage driver circuit, and low-voltage power devices, among others.

In the level-shifting device structure of particular embodiments, a low-voltage signal from the low-voltage side circuit may be input from the source terminal of the level-shifting MOS transistor, can pass through the doped region, and be transmitted to the drain terminal of the level-shifting MOS transistor in the high-voltage side region. The isolation structure may provide electrical isolation between the high-voltage and low-voltage side circuits. However, since the level-shifting MOS transistor is arranged to pass through the isolation structure, the integrity of the layout can be compromised in some cases, and the voltage withstand capability of the level-shifting MOS transistor may be lower than that of the isolation structure, thus making the level-shifting MOS transistor susceptible to damage during ESD testing. Additionally, in some cases, the interface charge density at the junction between the drain region and the isolation structure can be relatively high, which may create a strong electrostatic field and hinder improvements in the device's voltage withstand capability.

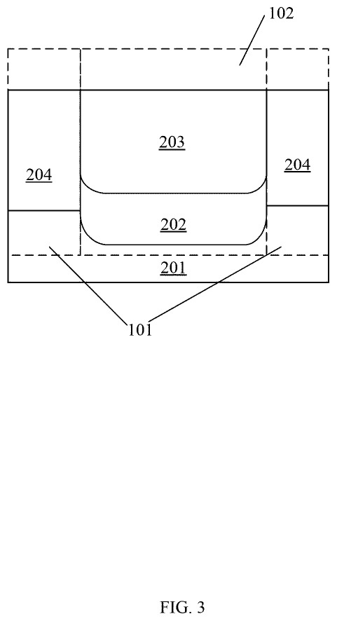

Referring now to FIG. 3, shown is a cross-sectional view of the first example level-shifting device structure along a line ‘cd’ in FIG. 2A, in accordance with embodiments of the present invention. The level-shifting device structure can include level-shifting MOS transistor 102 and isolation structure 101. Level-shifting MOS transistor 102 can include epitaxial layer 202 located in substrate 201, and “first” doped region 203 located in epitaxial layer 202. For example, the drain region and the source region of the level-shifting MOS transistor can be located in doped region 203.

Isolation structure 101 can include “second” doped region 204 located in substrate 201. In other examples, isolation structure 101 may also include epitaxial layer 202, and doped region 204 can be located in epitaxial layer 202. Further, isolation structure 101 may also include a buried layer located below doped region 204. Substrate 201, epitaxial layer 202, doped region 204, and the buried layer can be of a first doping type, and doped region 203 can be of a second doping type. In this particular example, the first doping type is P-type, and the second doping type is N-type.

It should be noted that the cross-sectional view in FIG. 3 is simplified to clearly illustrate the positional relationship between level-shifting MOS transistor 102 and isolation structure 101. Certain embodiments may also include further structural details, as one skilled in the art will recognize.

The cross-sectional view of the first example level-shifting device structure along a line ‘ab’ in FIG. 2A can correspond to a traditional LDMOS device structure, whereby a traditional high-voltage side circuit located inside the LDMOS device and a traditional low-voltage side circuit located outside the LDMOS device are not shown. The level-shifting MOS transistor can include source region 131, drain region 121, and doped region 141. Source region 131 can include a source doping region and a body contact region, and may further include a body region. The source doping region and the body contact region can be located in the body region. Drain region 121 can include a drain doping region. The current channel between source region 131 and drain region 121 may flow along the surface of doped region 141.

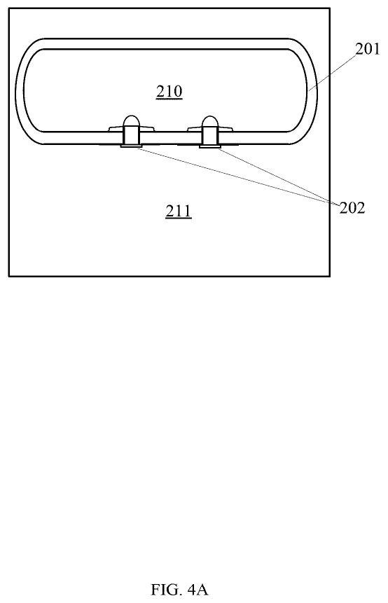

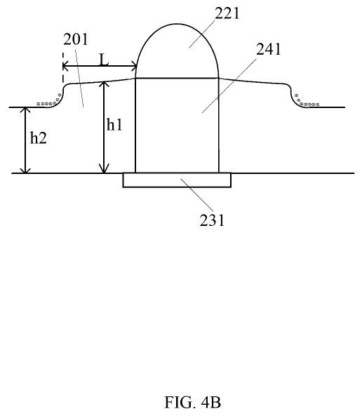

Referring now to FIGS. 4A and 4B, shown are a top view diagram and a partially enlarged view block diagram, respectively, of a second example level-shifting device structure, in accordance with embodiments of the present invention. In this particular example level-shifting device structure, thickness h1 of the isolation structure near doped region 241 can be set to be greater than thickness h2 of the isolation structure in other regions. In this particular example, the thickness of the isolation structure near doped region 241 can increase toward high-voltage side region 210. The width of doped region 241 between drain region 221 and source region 231 can be greater than or equal to the width of isolation structure 201. The thickened portion of the isolation structure near doped region 241 can be set to be thickness h1; that is, the thickness of the thickened portion may be the same. In other examples, thickness h1 of the thickened portion of the isolation structure may gradually decrease in a direction away from the doped region.

In this embodiment, the length of the thickened portion of the isolation structure adjacent to the doped region can be from about 70 μm to about 130 μm, and thickness h1 of the thickened portion of the isolation structure near the doped region can be from about 30 μm to about 50 μm. The junction between the isolation structure and the drain region can be set to be arc-shaped, and the junction between the thickened portion and the non-thickened portion of the isolation structure may also be set to be arc-shaped to ensure a smooth transition. This can reduce charge accumulation at sharp edges and minimize electric field peaks, thereby improving the voltage withstand capability of the level-shifting device structure.

By increasing the thickness of the isolation structure near the doped region, particular embodiments may effectively increase the thickness of the doped region of the level-shifting MOS transistor. The doped region can serve as the drift region of the MOS transistor, and increasing the thickness of the drift region may enhance the voltage withstand capability of the MOS transistor.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. A level-shifting device structure, comprising:
a) a level-shifting MOS transistor located in a semiconductor region, wherein the level-shifting MOS transistor comprises a source region, a drain region, and a doped region;
b) an isolation structure extending from both sides of the doped region to form a closed ring shape, in order to divide the semiconductor region into a high-voltage side region enclosed by the isolation structure and a low-voltage side region located outside the isolation structure; and
c) wherein the drain region is disposed in the high-voltage side region, and the source region is disposed in the low-voltage side region.

2. The level-shifting device structure of claim 1, wherein a thickness of the isolation structure near the doped region is greater than a thickness of the isolation structure in other regions.

3. The level-shifting device structure of claim 1, wherein an entire thickness of the isolation structure is uniform.

4. The level-shifting device structure of claim 1, wherein a thickness of the isolation structure near the doped region increases toward the high-voltage side region.

5. The level-shifting device structure of claim 1, wherein a thickness of the doped region is greater than or equal to a maximum thickness of the isolation structure.

6. The level-shifting device structure of claim 4, wherein a thickness of a thickened portion of the isolation structure is uniform.

7. The level-shifting device structure of claim 4, wherein a thickness of a thickened portion of the isolation structure decreases in a direction away from the doped region.

8. The level-shifting device structure of claim 4, wherein a junction between a thickened portion and a non-thickened portion of the isolation structure is arc-shaped to ensure a smooth transition.

9. The level-shifting device structure of claim 1, wherein a junction between the isolation structure and the drain region is arc-shaped.

10. The level-shifting device structure of claim 1, wherein the isolation structure is P-type doped.

11. The level-shifting device structure of claim 4, wherein a length of a thickened portion of the isolation structure adjacent to the doped region is in a range from 70 μm to 130 μm.

12. The level-shifting device structure of claim 4, wherein a thickness of a thickened portion of the isolation structure near the doped region is in a range from 30 μm to 50 μm.
